(19) United States
(12) Patent Application Publication
(10) Pub. No.: US 2022/0112597 A1
(43) Pub. Date: Apr. 14, 2022

(54) TRANSPARENT NANO LAYERED WATER BARRIERS AND METHODS FOR MANUFACTURING THE SAME

(71) Applicant: U.S. Army DEVCOM Army Research Laboratory, Adelphi, MD (US)

(72) Inventors: Thomas C. Parker, Bel Air, MD (US); Richard T. Welker, Erding (DE)

(21) Appl. No.: 17/491,530

(22) Filed: Oct. 1, 2021

Related U.S. Application Data
(60) Provisional application No. 63/089,281, filed on Oct. 8, 2020.

(51) Int. Cl. C23C 16/40; C23C 16/50; B05D 1/00

(52) U.S. Cl. CPC C23C 16/401; B05D 1/62; B05D 1/60; C23C 16/50

(57) ABSTRACT

We present a novel technology to prevent water absorption into substrates and to prevent the hydrolysis process thereof. To these ends, we disclose very thin-film water-vapor barrier for applications to substrate surfaces and methods for manufacturing the same. A polymeric compound film and silica-like compound film form a bilayer and one or more bilayers form the barrier on the substrate. The thickness of the film layers is kept below the thin film interference thickness to ensure that the one or more transparent bilayers are substantially transparent to the light. The thin film interference thickness may be characterized as the wavelength of light (λ) divided by four (4) times the index of refraction (n) of the film materials.

### RELATED APPLICATION DATA

This patent application claims the benefit of U.S. Provisional Patent Application No. 63/089,281 filed on 8 Oct. 2020, the disclosure of which is herein incorporated by reference in its entirety for all purposes.

### GOVERNMENTAL INTEREST

The invention described herein may be manufactured, used and licensed by or for the U.S. Government.

### BACKGROUND

### Field

The field of the invention relates to transparent materials and vapor barriers and, in particular, to transparent nano-layered water barriers and methods for manufacturing the same.

### Description of Related Art

Polycarbonate is a commonly used material for transparent applications when it is desirable to reduce weight and/or shattering compared to glass. Polycarbonate, though, readily absorbs water vapor (e.g., 0.3-0.5 Wt. %).

Silica (SiO₂) coatings are typically applied to polycarbonate to protect the polycarbonate from scratches and abrasion, i.e. as a scratch-resistant coating. Such coatings are typically on the order several microns thick. Silica films are also known to be excellent water barriers; however, they are subject to defects, such as pinholes, which act as fast diffusion pathways for water molecules. Polymeric protective coating films are also used. While polymeric coating films are less susceptible to pinhole formation, they are not as effective as water barriers. Water molecules are therefore still readily absorbed into the bulk of the polycarbonate even with these traditional types of water barrier coatings. The absorbed water vapor is known to cause thermo-hydrolytic damage to the chemical bonds within the polycarbonate changing the material's chemical state. These chemical state changes result in degradation of the optical, mechanical, and bonding properties. The absorbed water vapor can cause reduced visibility across spectral range including the infrared spectrum. It is also believed that water vapor causes delamination of the barrier coating from the polycarbonate. Windows that delaminate must be replaced as they can no longer have the required transparency to act as a window.

There are several suspected causes of delamination in transparent armor. These include thermal stresses during fabrication, mechanical stresses due to machining/fabrication errors in the steel frame, mechanical stresses when the steel frame is attached to the vehicle, and particulate (or other defects) at the bond interfaces from the initial fabrication. However, multiple groups have observed that without heat and humidity the incidence of delamination is much reduced and/or nonexistent in accelerated aging studies. In particular, when heat and humidity are present the innermost layer, composed of polycarbonate, is subject to degradation. This material has been known for many decades to readily undergo hydrolysis at temperatures above 60° C. This hydrolysis process creates mobile molecular fragments such as biphenyl A (BPA), which can readily migrate to bonding interfaces. Once at these interfaces, small molecules such as BPA can interrupt the bond interface and in principle, decrease the bonding strength. This reduction in bond strength could be a contributing factor in the delamination of polycarbonate and the thermoplastic polyurethane in transparent armor.

### SUMMARY

We present a novel technology to prevent water absorption into substrates and to prevent the hydrolysis process. To these ends, we disclose very thin-film water-vapor barriers for applications to substrate surfaces and methods for manufacturing the same. A polymeric compound film and silica-like compound film form a bilayer and one or more bilayers form the barrier on the substrate. The barrier and preferably both the substrate and the barrier are transparent to light.

More particularly, according to embodiments, a transparent water vapor barrier comprises a substrate and one or more transparent bilayers formed on the substrate. Each transparent bilayer comprises a first layer formed of a polymer film comprising a polymeric compound of Si, O and C, and a second layer formed of a nearly carbon-free film comprising a silica-like compound of Si and O. The thickness of the layers is kept below the thin film interference thickness to ensure that the one or more transparent bilayers are substantially transparent to the light. The thin film interference thickness may be characterized as the wavelength of light (λ) divided by four (4) times the index of refraction (n) of the film materials.

The silica-like compound may have a stoichiometry of approximately SiO_{1.75}C_{0.008}, for instance. And the nearly carbon-free film may comprise less than about 1 atomic percent carbon. The silica-like compound of Si and O comprises SiO_{X}, where 1.25<X<2. For instance, the polymeric compound may have a stoichiometry of approximately SiO_{0.6}C_{1.7}.

The substrate may preferably comprise transparent armor or a window. It may be formed of polycarbonate, polyvinyl alcohol, acrylonitrile butadiene styrene, or nylon, as non-limiting examples. For visible light, λ, may be approximately 380 nm and n may be approximately 1.4-1.55. Thus, each film of the one or more transparent bilayers may be no more than approximately 60 nm in thickness.

We also present processes to apply a nano-layered water vapor barrier to substrate surfaces. More particularly, we present embodiments that use a plasma-enhanced chemical vapor deposition process (PECVD) to grow the thin, transparent water barriers on the substrate surface. The polymeric compound film and silica-like compound film are alternatively applied forming the one or more transparent bilayers using this technique. By alternating thin, nano-layers of the polymeric compound and silica-like compound, a superior thin-film water-vapor barrier can be achieved. The barrier coatings can be applied directly to substrates to provide the water vapor barrier. These coatings preferably maintain the transparency of the substrates by keeping the layers' thicknesses below a critical thickness at which optical interference occurs. The reduction in water intrusion into the substrate helps to prolong the service life of the coated substrates by increasing the time to delamination and embrittlement of the (inner) substrate in the barrier assembly.

Both the polymeric compound film and silica-like compound film are formed using the same precursor gases which may include hexamethyldisiloxane (HMDSO) and oxygen (O₂). The chemistry of the two films is judiciously controlled via the oxygen to carbon ratio in the deposition chamber. The amount of HMDSO and/or oxygen gas admitted to the deposition chamber can be controlled and varied to change the O to C ratio. An inert working gas is admitted to the chamber to generate plasma. It can also be used to vary the concentration of the gases and to change the O to C ratio.

More specifically, according to embodiments, a method for forming a transparent water vapor barrier comprises placing a substrate in a chamber and varying the oxygen:carbon ratio of the HMDSO and oxygen precursor gases supplied to the chamber in a deposition process to form one or more transparent bilayers on the substrate. Again, each transparent bilayer comprises a first layer formed of a polymer film comprising a polymeric compound of Si, O and C; and a second layer formed of a nearly carbon-free film comprising a silica-like compound of Si and O. The thickness of the layers is kept below the thin film optical interference thickness to keep the one or more transparent bilayers substantially transparent to the light. And, to repeat, the thin film interference thickness may be characterized as the wavelength of light (λ) divided by four (4) times the index of refraction (n) of the deposited film materials.

The deposition process may preferably comprise plasma assisted chemical vapor deposition with a suitable apparatus with a deposition chamber which may be a vacuum chamber. The oxygen:carbon ratio of the precursor gases is controlled to form the two films of the bilayer(s). For instance, that ratio may be approximately 0.34:1 to form the polymer film. And it may be approximately 6:1 to form the nearly carbon-free film. The method can further include cleaning the substrate before placing it into the deposition chamber. The method may include lowering the pressure in the deposition chamber to about 0.02 mbar or less. More, it can further comprise generating a plasma within the deposition chamber to activate the surface of the substrate before forming the one or more transparent bilayers. And, the method can further comprise supplying a working gas to the deposition chamber to vary the oxygen:carbon ratio of the precursor gases. The working gas may be a noble gas, such as argon, krypton, helium, neon or xenon, as non-limiting examples.

These and other embodiments of the invention are described in more detail, below.

### DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only illustrative embodiments of this invention and are therefore not to be considered limiting of its scope, for the invention may admit to other equally effective embodiments.

FIG. 1 is a schematic of a transparent nano-layered water vapor barrier according to embodiments.

FIG. 2A is a schematic of a plasma assisted chemical vapor deposition apparatus used to form transparent nano-layered water vapor barrier according to embodiments. FIG. 2B is flowchart showing a method for performing plasma assisted chemical vapor deposition to form transparent nano-layered water vapor barriers according to embodiments.

FIG. 3A shows images of droplet shapes for water and diiodomethane on barrier film samples that were produced. FIG. 3B is a plot of the total surface free energy (SFE) calculated using the OWRK (Owens, Wendt, Rabel and Kaelble) method for the film samples.

FIG. 4A shows high-resolution X-ray photoelectron spectroscopy (XPS) of the C 1s peaks for the samples. FIG. 4B shows the high-resolution scans of the elemental composition used to calculate the atomic percent (At. %) composition of each sample film.

FIGS. 5A and 5B show the high-resolution XPS of the Si 2p peaks for the polymeric thin film (FIG. 5A) and the silica-like film (FIG. 5B), respectively.

FIG. 6 is a cross-sectional scanning electron microscopy (SEM) image for an eleven-layer thin-film stack forming a transparent nano-layered water vapor barrier according to an embodiment.

FIG. 7A is a schematic of the testing setup used to conduct water-transmission measurements of samples. FIG. 7B shows the results of the water-transmission measurements for the samples coated with the 11-layer transparent nano-layered water vapor barrier versus uncoated low-density polyethylene (LDPE) films.

FIG. 8 shows optical transmission data for a series of samples having transparent nano-layered water vapor barriers deposited.

FIG. 9 shows atomic force microscopy (AFM) images of deposited thin films as used in transparent nano-layered water vapor barriers.

FIG. 10 shows the root mean squared (RMS) roughness of the films produced as used in transparent nano-layered water vapor barriers.

### DETAILED DESCRIPTION

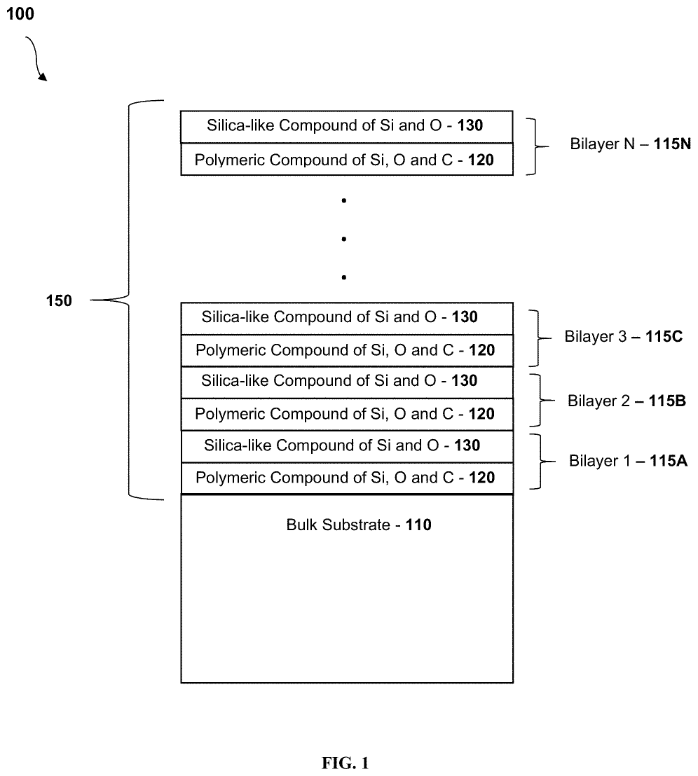

FIG. 1 is a schematic of a transparent nano-layered water vapor barrier 100 according to embodiments. It shows a side profile view.

The transparent nano-layered water vapor barrier 100 is formed on outer surface(s) of a substrate 110 and comprises one or more transparent bilayers 115 (115A, 115B, 115C . . . 115N). Each of the transparent bilayer(s) 115 includes (i) a first layer 120, and (ii) a second layer 130. Together, the one or more transparent bilayers 115 form a transparent nano-layered water barrier 150. The first and second layers 120 and 130 of the bilayer(s) 115 have different chemical compositions and properties, yet they synergistically provide a water barrier 150 that is also transparent to light of a desired spectra. The transparent nano-layered water barrier 150 protects the underlying substrate 110 from damage due to water hydrolysis of the bonds in the substrate material. It thus prolongs the in-service lifetime of substrate. More particularly, the transparent nano-layered water vapor barrier 100 provides protection of substrate construction materials from thermohydrolytic aging. This aging can effect both mechanical stability as well as transparency/color stability.

The substrate 110 may preferably comprise transparent armor or a window. For instance, it may be formed of a transparent polymer. One such example is polycarbonate which is highly transparent. Polycarbonates are a group of thermoplastic polymers containing carbonate groups in their chemical structures. The main polycarbonate material is produced by the reaction of bisphenol A (BPA) and phosgene (COCl₂). Polycarbonate substrates are commercially-available in many different stock shapes and forms. Other transparent substrate 110 materials may also be used including, but are not necessarily limited to: polyvinyl alcohol, acrylonitrile butadiene styrene, or nylon. In some cases, the as-received substrate can be already integrated in a transparent armor assembly, a monolithic piece, or any intermediate produce or step in between. The substrate 110 might also be opaque or partially opaque in some embodiments. The transparent barrier 150 would permit at least the surface of such a substrate to be viewed, such as to read text and/or view other indicia like numbering or symbols.

The substrate 110 may range in thickness from a few millimeters to a few centimeters or even thicker, for instance, depending on their applications and/or desired properties (such as for strength and durability). The substrate 110, once having the barrier 150 applied, is considered a part of transparent nano-layered water vapor barrier 100.

The transparent bilayer(s) 115 slow water intrusion into the surface of the substrate 110. The bilayers 115 may be deposited on the substrate 110 by alternatively forming first and second layers 120, 130. In some instances, an odd layer of the first layer 120 and/or the second layer 130 may be provided for in the barrier 150 in addition to one or more bilayers 115. The individual layers are kept thin enough to maintain transparency.

In principle, and contemplated in embodiments, the transparent nano-layered water vapor barrier 100 might have as few as a single bilayer 115. In actuality, there likely will be many bilayers 115. In some embodiments, there could be at least 10 bilayers 115. In others, there may be considerably more, such as 80-100 bilayers 115. As a first order approximation, the water vapor mass transport rate can be estimated by a linear approximation, for instance, where two bilayers will permit half as much mass transport as one bilayer.

According to embodiments, as further discussed below, plasma assisted chemical vapor deposition may be used to deposit those layers 120, 130. Plasma assisted chemical vapor deposition is considered a low-temperature disposition process which can be conducted on substrates at a temperature of less than 50° C. This methodology is an improvement compared to conventional deposition processes which require much higher temperature, especially, for substrate materials which might not be suitable for that degree of heating.

This deposition technique can be performed on an as-received substrate 110, such as transparent armor or a window. Typically, substrates 110 are planar or at least mostly planar. The lateral size of planar substrates that can be coated is generally only limited by the size of the deposition chamber of the apparatus. Plasma assisted CVD is primarily a line of sight deposition technique. (While there is some non-line of sight deposition, it is not that uniform and is much less than the line of sight surfaces). Geometries that have internal surfaces or surfaces not exposed to the plasma will not be coated uniformly.

The first layer 120 is formed of a polymer film comprising a polymeric compound of silicon (Si), oxygen (O) and carbon (C). And the second layer 130 is formed of a nearly carbon-free film comprising a silica-like compound of Si and O.

The polymeric compound of the first layer 120 is similar to organosilicon polymer films. These films have an amorphous or glass like crystalline state. The polymeric compound may have the chemical formula SiO_{X}C_{Y}, where 0.5<X<2 and Y<2.

Conventional silica films deposited by chemical vapor deposition techniques are known to have “pinhole” defects that permits fast transport of water molecules. The polymeric compound of the first layer 120 adds a more polymeric-like film to the bilayers 115 which makes the second layer 130 less susceptible to these pinhole defects.

The second layer 130 is formed of a nearly carbon-free film comprising a silica-like compound of Si and O. It is intended to mimic silica. Conventional silica is a compound formed of Si and O has a chemical formula and a stoichiometry of SiO₂. A carbon source, albeit a very small one, is likely present in the deposition chamber of the plasma assisted CVD apparatus due very small amounts of the HMDSO gas (and/or intermediate carbon sources) remaining present there, but the amount is believed to be very low. Thus, as used herein, the term “nearly carbon-free” is defined as less than about 1 atomic percent carbon (or 0.01 carbon stoichiometrically). And, as used herein, the term “silica-like compound” is defined as, not silica per se, but a compound of predominantly of Si and O having similar physical and chemical properties as silica. For instance, a silica-like compound of Si and O may have the chemical formula SiO_{X}, where L25<X<2. And a “nearly carbon-free silica-like compound” may have the chemical formula SiO_{X}C_{Y}, where 1.25<X<2 and Y<0.01.

In some embodiments, the polymeric compound of the first layer 120 has a stoichiometry of approximately SiO_{0.6}C_{1.7} and the silica-like compound of the second layer 130 has a stoichiometry of approximately SiO_{1.75}C_{0.008}.

The transparent bilayer(s) 115 are used to slow water intrusion into the substrate 110. Transparency should be greater than 90% and more preferably in excess of 95%. The individual layers of are thin enough to maintain transparency to light. The term “light” as used herein is defined as electromagnetic radiation in the so-called optical radiation spectrum; this typically include the ultraviolet (10-400 nm), visible (380-750 nm) and/or infrared (700 nm-1 mm) spectra. The visible spectrum, in particular, is primary importance for many applications involving or relating to people, in that is the spectra we use to “see.”

The thickness of the one or more bilayers 115 may be limited by processing time and any interlayer adhesion failure due to stress build up. In theory, the total thickness of each bilayer 115 could go to the range of perhaps 10 micrometers (e.g., 5 μm on average for first layer 120 and the second layer 130). But the thickness affects the transparency of light passing through it.

To maintain sufficient transparency of the bilayer 115, the thickness must be limited. That is, the optical thin film interference occurs when films are too thick. This maximum thickness is wavelength dependent. In general, the smaller the wavelength of light, lambda k, the smaller the optical thickness of the layer needs to be to cause the interference. We keep the thickness of the both the first layer 120 and the second layer 130 below the thin film interference thickness of the wavelength of light (lambda λ) divided by four (4) times the index of refraction (n) of the deposition material. (See Equation 6.31.b in the textbook: Germain Chartier, Introduction to Optics, Springer, 2005, Section 6.5.2, “Antireflection Coatings,” pp. 290-291, herein incorporated by reference). This ensures that the one or more transparent bilayers 115 are substantially transparent to the light. So the upper-energy (low-bandwidth) edge of the visible spectrum (e.g., 380 nm) is used to set the largest layer thickness the bilayer 115 can have while not causing optical interference to visible light.

The thickness limit for a bilayer 115 is derived for the higher optical index material, i.e., the silica-like compound, of the second layer 130. We assume an optical index for it of pure silica (SiO₂). The index of refraction (n) of silica is wavelength dependent; it varies between about 1.45 and 1.25 for wavelengths of light between about 2 and 6 microns. For instance, see data provided in I. H. Malitson, “Interspecimen comparison of the refractive index of fused silica,” J. Opt. Soc. Am. 55, 1205-1208 (1965), herein incorporated by reference in its entirety. (Note: An online Refractive index database of Malitson's data with interactive tool is available at: https://reffaciveindex.info/?shelf=glass&book=fused_silica&page=Malitson). More particularly, at approximately 380 nm, i.e., the threshold of the visible spectra, the index of refraction (n) of fused silica is 1.4725 using that tool. This gives a thickness limit for silica of 64.5161 nm.

We more broadly assume the value of n for the silica-like compound of the second layer 130 in a range of about 1.4-1.55 as an estimate. This give a range of critical thickness of 61.2903 to 67.8571 nm for the silica-like compound of the second layer 130. We chose a thickness limit of 60 nm. (Note: with more data and proper refractive index measurements, more precise thickness values for the silica-like compound film might be determined). In some embodiments, we use a thickness of about 10 nm for that layer.

The polymeric compound of the first layer 120 has a lower index and, in principal, can be thicker. But, for simplicity sake, especially for manufacturing, we chose to make the first layer 120 and the second layer 130 the same thickness. Hence, as a non-limiting example, the thickness of layers 120 and 130 may each be 60 nm, so a total thickness limit may be 120 nm for the transparent bilayer(s) 115. They do not have to be the same thickness though and indeed, in other embodiments, their thicknesses may differ. (Again, with more data and refractive index measurements, more precise thickness values for the films might be determined).

The aforementioned thickness limit values were determined for the transparency of light in the visible spectrum. They would need to change to ensure transparency in other light spectra or sub-spectra.

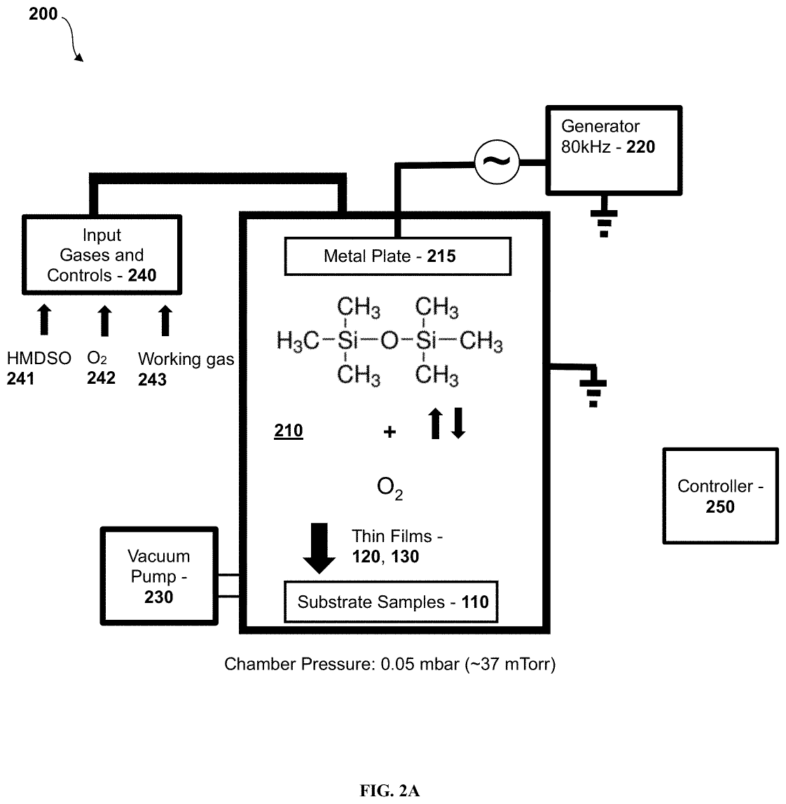

FIG. 2A is a schematic of a plasma assisted chemical vapor deposition (CM) apparatus 200 used to form transparent nano-layered water vapor barriers according to embodiments. Plasma assisted chemical vapor deposition apparatus are known and commercially-available. They are ideal for depositing coating layers on low-temperature substrates.

For instance, the plasma-assisted CVD apparatus 200 may be a ‘Nano’ Low pressure plasma system model plasma system manufactured by Diener electronic GmbH. (Ebhausen, Germany) as one non-limiting example. More information is available online about the ‘Nano’ model at: https://www.directindustry.com/prod/diener-electronic/product-50802-469801.html, herein incorporated by reference in its entirety. Other commercially-available plasma assisted CVD apparatuses may be used in other embodiments and those skilled in the art should equally appreciate how to use them accordingly.

Since the hardware of the apparatus 200 is well known, the key elements will be briefly explained with respect to the apparatus's configuration and operation for producing a transparent nano-layered water vapor barrier 100.

The deposition chamber 210 is where the substrate 110 is placed for depositing the various layers to form a transparent nano-layered water vapor barrier 100 according to embodiments. It is suitably-sized for deposition. (For instance, the ‘Nano’ model chamber volume can vary from 18-36 Liters based on the device version). The deposition chamber 210 includes a top metal plate 215 connected to a plasma generator 220, which generates a plasma in the chamber 210.

The vacuum pump 230 is used to drawn down and maintain a vacuum in the deposition chamber 210 and related parts. The pump 230 may be an oil-based mechanical pump that can pump corrosives and oxidizers such as oxygen (O₂) as a non-limiting example. The deposition chamber 210 and associated parts can be evacuated down to a few hundredths of an mbar, for instance. During a deposition, the pressure is maintained at approximately one-half of an mbar or lower. The plasma is sustained by varying the voltage sinusoidally with the plasma generator 220; it may be operated at a rate of 80 kilohertz, for example. The alternating signal is connected via feedthrough to the metal plate 215 at the top of the chamber 210 where the plasma in produced.

Supplied here are hexamethyldisiloxane (HMDSO) 241, oxygen (O₂) 242, and a working gas 243 for film depositions. They can be readily sourced from a chemical supplier such as Sigma-Aldrich. These precursor gases are input and controlled at 240, which includes the various gas tanks, piping, valves, pressure and flow gauges, pressure-regulated controls, and dials/displays/read-outs, etc. to supply and control the flow of gases for plasma deposition. Needle valves may be used to control the flow rates of these gases 241, 242, and 243, for instance.

For hexamethyldisiloxane-based depositions, the HMSDO gas 241 is introduced, via the gas input/controls 240, into the deposition chamber 210. The source of the HMSDO may be a pressurized external liquid source which yields HMSDO gas or vapor. The oxygen 242 and working gas 243 may be are separately controlled with the gas input/controls 240. The gases 241, 242, and 243 may be controlled by separate mass flow controllers and then mixed to achieve the desired gas ratios within the chamber 210, as a non-limiting example.

HMDSO 241 is an organosilicon compound with the formula O[Si(CH₃)₃]₂ (or C₆H₁₈Si₂O). Its structure is shown below:

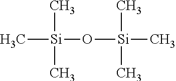

The HMDSO 241 reacts with O₂ 242 in the deposition chamber 210 to form a solid film deposition of either layer 120 or layer 130 on top surface of the substrate 110. Depending on the oxygen to carbon ratio of these precursor gases in the chamber 210, the resulting compound of the layer being deposited will vary. The working gas 243 is used to produce plasma. The working gas 243 should be inert such that it which will not react with the other gases and/or the substrate during the deposition process. For instance, the noble gases: helium (He), neon (Ne), argon (Ar), krypton (Kr) and xenon (Xe) may be used as non-limiting examples.

To form one or more bilayers 115, first layers 120 and second layers 130 are alternatively formed by repeatedly changing this ratio. We have found that the key factor that controls the stoichiometry of the deposited thin-films' chemistry is the number of oxygen (O) atoms versus the number of carbon (C) atoms entering the chamber per second. The working gas 243 may also be used to vary the oxygen:carbon ratio of the precursor HMDSO gas 241 and 02 gas 242 in the deposition chamber 210.

If there are far more O atoms in the plasma than C atoms, some O will bond with the silicon (Si). The remaining O species will etch the C, forming volatile compounds that will be pumped away, such as carbon dioxide (CO₂) and/or carbon monoxide (CO). As the needle valve does not give an absolute number of HMDSO molecules passing into the chamber, it is necessary to use the equilibrium pressure to calculate the ratio of the gases and HMDSO vapor in the chamber, which is done by using the ideal gas law shown in Eq. 1, where P is the pressure in the chamber, V is the volume the gas occupies in the chamber, N is the number of moles, k is Boltzmann's constant and Tis the temperature in kelvin. As we are looking for ratios, the V, k, and T cancel out leaving the ratios of the pressures, which equals the ratio of the number of moles of the respective gasses. Once the elemental ratios, O to C, are selected, the molar ratio of the individual gasses can be simply calculated using the chemical formulas, specifically O₂ (oxygen) and C₆H₁₈Si₂O (HMDSO). Then, with the input gas and molar ratios known, the partial pressures of the individual gasses are set by flowing each gas individually and measuring the pressure. This approach removes the need of an expensive, heated mass-flow controller capable of metering the HMDSO vapor.

PV=NkT (1)

The plasma products from the input gasses and vapor deposit on the substrate 110 shown at the bottom of chamber 210. The apparatus 200 is controlled via control means or controller 250. The control means or controller 250 may include physical control means, such as knobs, buttons, switches, levers, gauges, or the like for controlling and monitoring various parameters of the apparatus 200. It may also include semi-automatic or fully-automatic control systems as known for such apparatuses. For instance, software applications exist which can integrate with the apparatus 200 to control its functionality. (See, “Plasma Technology” guide, 4^{th} ed. 2011, published by Diener electronic, herein incorporated by reference in its entirety).

FIG. 2B is flowchart showing a method 280 for performing plasma assisted chemical vapor deposition to form transparent nano-layered water vapor barrier according to embodiment. It uses the apparatus 200 depicted in FIG. 2A.

Step 281: Initial Substrate Cleaning: A substrate 110 is received and its surface is cleaned with a compatible solvent and particle free wipe to remove the bulk of the residual adhesive from the protective film and/or any contaminants on the surface from previous processing. For instance, the received substrates 110 may be immersed in deionized water at 66° C. until saturated (e.g., 0.4% by weight) and then dried at that temperature under vacuum.

Step 282: Placement in Vacuum Chamber: Next, the substrate 110 is loaded into the deposition chamber 210 for coating with one or more bi layers of the polymeric compound film and silica-like compound film to form the nano-layered transparent water barrier 100.

Step 283: Setting Film Chemistry: Once the chamber 210 has reached its base vacuum level, typically on the order of 0.02 mbar or less, the molecular ratios of the HMDSO and Oxygen precursor gases are set. The HMDSO valve is opened and the needle valve is adjusted to attain a predetermined chamber pressure. This sets the molecular flow rate of the HMDSO. Next, the Oxygen gas flow rate (in standard cubic centimeters per minute) is set to attain a predetermined system pressure. The predetermined pressures and the Oxygen to Carbon ratios are used control the chemistry of the deposited films. A 6:1 ratio (Oxygen:Carbon) has been determined through experimentation and measure with x-ray photoelectron spectroscopy to yield nearly carbon free silica-like films with a stoichiometry of SiO_{1.75}C_{0.008}. The working gas (e.g., argon) is used as the plasma working gas and the same HMDSO precursor with an Oxygen to Carbon ratio 0.35:1. X-ray photoelectron measurements show these films to have a stoichiometry of SiO_{0.6}C_{1.7} forming a polymeric composition. These film layers are repeated to the desired number of bilayers.

Step 284: In Vacuum Oxygen Pre-Cleaning: Once the chamber 210 has been evacuated to a suitable pressure, typically less than 0.3 mbar, the pre-cleaning and surface activation step is conducted. The pre-cleaning and surface activation occurs at a nominal pressure of 0.4 mbar, with upstream pressure control, where the gas flow is automatically modulated to maintain the fixed chamber pressure of 0.4 mbar. Once the gas flow is stable a plasma is ignited using the low frequency (e.g., 80 kilohertz) plasma generator 220. The power applied is 500 watts and the run time is about 5 minutes, for instance.

Step 285: Deposition of the nano-layers: The deposition of the polymeric and silica-like layers is now conducted. It is a fully-scalable process. Each layer thickness may be controlled via the deposition time. We maintain the optical transparency and clarity of the deposited layers by avoiding optical interference effects. The layer thicknesses for the bilayer(s) are kept below the thin film interference threshold of lambda (wavelength of light) divided by four (4) times the index of refraction (n) of the deposition material. The higher energy (lower wavelength) end of the visible spectrum is 380 nanometers (i.e., the color violet). The silica-like has the higher optical refractive index (n=1.4 to 1.55) and is therefore more likely to cause interference effects. Using 380 nanometers for lambda and an index of 1.55 yields an interference effect for films 61.3 nanometers in thickness. By keeping our alternating film layers 120, 130 each at approximately 10 nanometers thickness, in an embodiment, we can maintain optical clarity of the substrate (e.g., polycarbonate) while adding the protective water vapor barrier.

Step 286: Substrate Removal: Once the deposition is completed, the chamber 210 is slowly vented over several minutes to minimize thermal shock and the production of particles. After venting, the coated substrate can be removed for inspection.

Machine-executable instructions (such as software or machine code) can be stored in a memory device (not shown) and will be executed by the control means or controller 250 as needed for implementing method 280. In some implementations, software code (instructions), firmware, or the like, may be stored on a computer or machine-readable storage media. The controller may be comprised of one or more processor devices. It will be appreciated they could be executed by distinct processors thereof or, in other implementations, by processors of distinct and separate controllers altogether. The processor(s) may be a programmable processor, such as, for example, a field-programmable gate array (FPGA) or an application-specific integrated circuit (ASIC) processor. The methodology disclosed herein may be implemented and executed by an application created using any number of programming routines. Of course, any number of hardware implementations, programming languages, and operating platforms may be used without departing from the spirit or scope of the invention.

The film chemistry is key to getting good water vapor resistance. We conducted a series of thin films depositions so as to vary the oxygen to carbon (O to C) ratios of the admitted gases. The O to C ratios were: 0.34:1, 2:1, 3:1, and 6:1. As the deposition apparatus we used does not have a base pressure of zero mbar, the amount of gas admitted is the change in pressure from the base pressure, for example, delta mbar. For the lowest O to C ratio (0.34:1), only the HMSDO was admitted to the chamber with a delta of 0.06 mbar along with 200 SCCM of Ar (delta 0.33 mbar), which acts as the working gas to maintain the plasma. The only O comes from the HMDSO molecule itself. For the 2:1 ratio, 65 SCCM of O₂ (delta of 0.20 mbar) was introduced along with HMDSO with a delta of 0.13 mbar. For the 3:1 ratio, 120 SCCM (delta of 0.33 mbar) of O₂ was introduced along with an HMDSO with a delta of 0.13 mbar. For the high O to C ratio (6:1), an O₂ flow of 130 SCCM (delta of 0.33 mbar) and an HMSDO delta of 0.6 mbar were introduced. All depositions were carried out with a fixed power level of 30% or 300 watts for 10 min yielding deposition rates of approximately 10 nm per min.

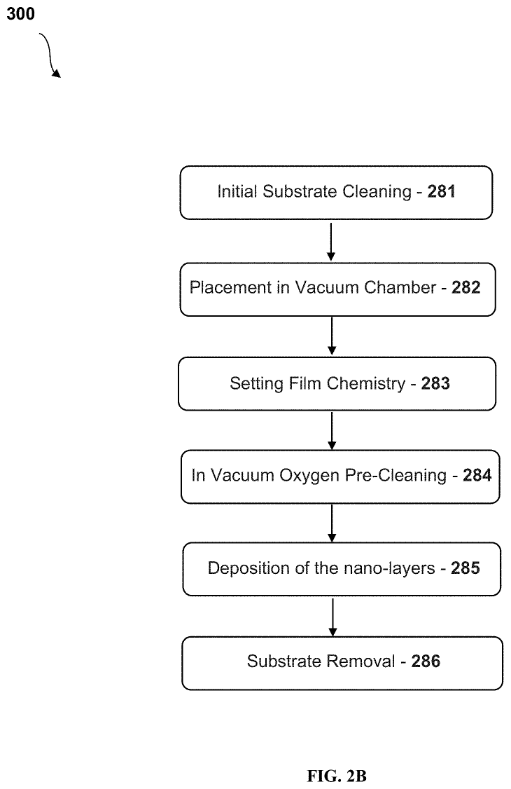

A DSA100 contact angle goniometer from Krüss GmbH (Hamburg, Germany) was used to measure the contact angles of the various thin-film surfaces. The contact angle of water and diiodomethane was measured at least 3 times on each sample, although typically the measurement was taken 10 times or more. FIG. 3A shows images of droplet shapes for water and diiodomethane on barrier film samples that we produced. Going from left to right, the samples had O to C ratios of 0.34:1, 2:1, 3:1, and 6:1 ratios. The droplet change is strongly affected by the O to C ratios of the input gasses. As expected, the droplets interact more strongly with the thin-film surface as the O to C ratio increases, resulting in a polymer-like surface (FIG. 3A, far left) and ending in an inorganic silica-like surface (FIG. 3A, far right).

To quantify the droplet interaction with the surface, we used Young's equation, as shown in Eq. 2, where σₛ is the surface free energy (SFE), σₛₗ is the interfacial tension between the liquid and solid, σₗ the surface tension of the liquid, and θ is the angle at the edge of the droplet and the surface of interest.

σₛ=σₛₗ+σₗ·cos θ (2)

The change in contact angle (θ) can be clearly seen in FIG. 3A where the water droplet in the upper left is approaching a 90° contact angle and the water droplet farthest right has a contact angle of approximately 25°. An example of theta (θ) is shown in the upper panel where the dotted line delineates the substrate droplet interface and the solid line shows the angle of the droplet at the interface. The contact angle theta is the angle between these two lines. In the droplet, the surface tensions of the liquids are known empirical values. Ultimately, we want to know the SFE. If we measure the contact angles of a mostly polar liquid (water) and a completely dispersive liquid (diiodomethane), we can apply the OWRK (Owens, Wendt, Rabel and Kaelble) method shown in Eq. 3, where the contributions of the polar (σₗ^{P}) and dispersive (σₗ^{D}) components of the liquids and the polar (σₛ^{P}) and dispersive (σₛ^{D}) components of the solid are modelled as a geometric sum.

σₛₗ=σₛ+σₗ−2(\sqrt{σₛ^{D}+σₗ^{D}}\sqrt{σₛ^{P}+σₗ^{P}}), (3)

FIG. 3B is a plot of the total SFE calculated using the OWRK method for the four samples we produced. The SFE of the films are shown and plotted as a function of the C atomic fraction as measured from X-ray photoelectron spectroscopy (XPS). The value of the SFE clearly increases as the C content decreases. The polymeric film with a 0.5 C fraction has an SFE of approximately 29 mJ/m². This is considered a low surface energy and comparable to something like Teflon (The Chemours Company, Wilmington, Del.) with an SFE of 20 mJ/m². On the other end of the graph (farthest right in the figure), the 6:1 O to C ratio sample has an SFE of approximately 60 mJ/m². This is in good agreement with the SFE values for glass, which is an amorphous SiO₂ surface and has an SFE of approximately 70 mJ/m². The data demonstrates that as the carbon content decreases the film goes from a more polymer structure to a more silica-like structure.

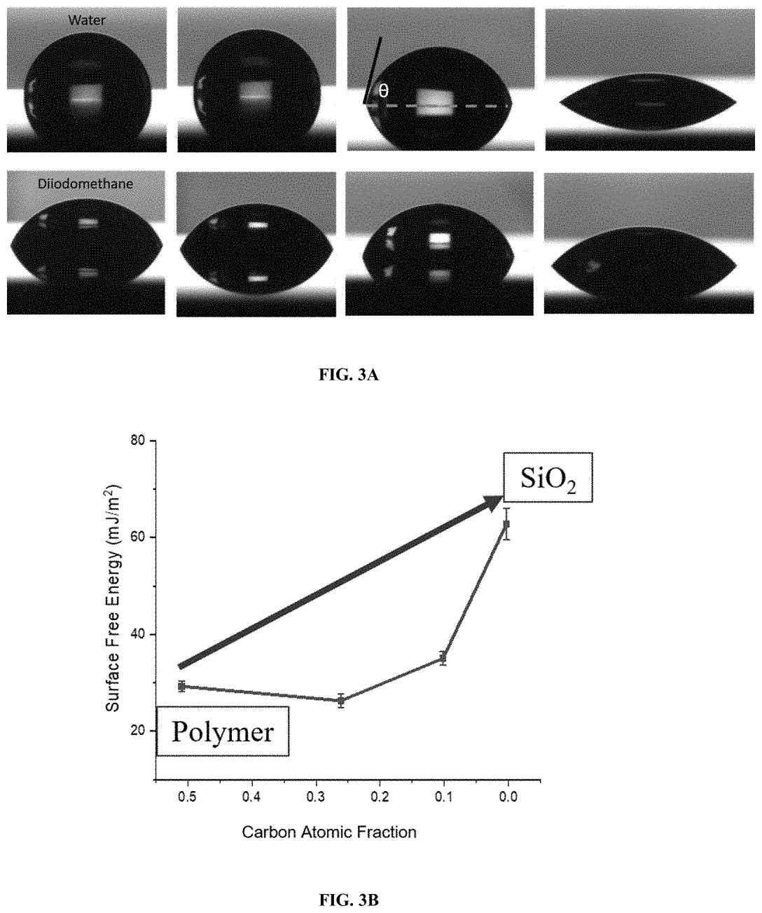

FIG. 4A shows high-resolution X-ray photoelectron spectroscopy (XPS) of the C 1s peaks for the different input gas O to C ratios used to produce the film samples. More particularly, these thin films were deposited for ˜10 minutes each). In these films, the O:C ratios were varied to have ˜100 nm final thickness (˜10 nm/min). The background for each scan was subtracted to permit scan-to-scan comparison. As can be seen, the 0.34:1 ratio has the highest C content. This C content reduces with increasing O to C ratio. In the 6:1 sample, the C content is extremely low and is difficult to observe visually.

FIG. 4B shows the high-resolution scans of the C, O, and Si that were used to calculate the atomic percent (At. %) composition of each film. The polymer-like film (farthest left) with the O to C ratio of 0.34:1 has a composition of SiO_{0.6}C_{1.7}, the 2:1 sample has a composition of SiO_{1.32}C_{0.9}, the 3:1 sample has a composition of SiO_{1.57}C_{0.29}, and the 6:1 sample has a composition of SiO_{1.76}C_{0.008}.

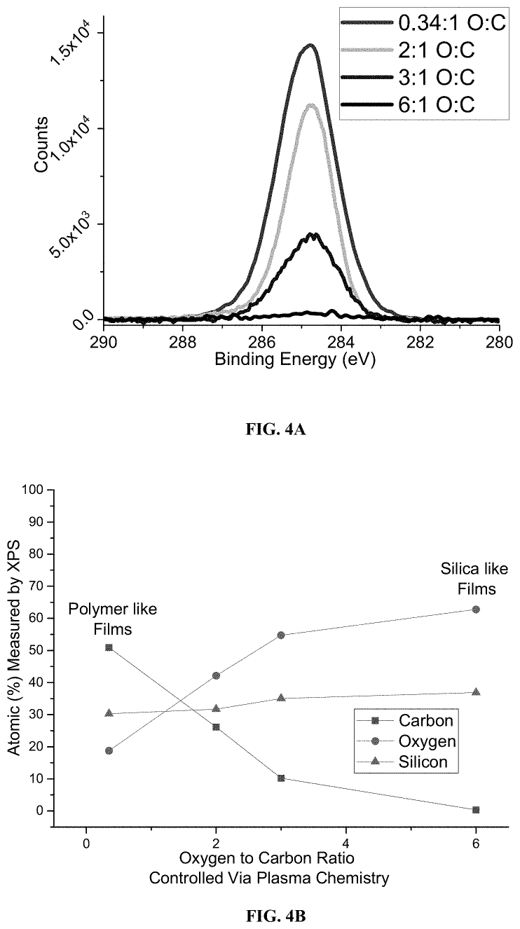

FIGS. 5A and 5B show the high-resolution XPS of the Si 2p peaks for the polymeric thin film (FIG. 5A) and the silica-like thin film (FIG. 5B), respectively. Along the x-axis is the binding energy of the photoelectrons and along the y-axis is the relative intensity. The fitting parameters of the respective peaks are shown at the top of each scan. On the left, the fitting of the Si 2p for the polymer film shows a peak position of 102.21 eV and a full width at half maximum of 2.13 eV. As a reference, the peak position for pure Si would be 99.4 eV. For a silicone material, the expected binding energy would fall at approximately 102.4 eV, which is in good agreement with our polymer film. For the peak on the right with the 6:1 O to C ratio, it has a fitted-peak position of 103.74 eV, which is in very good agreement with the expected value for SiO₂ of 103.5 eV. The full width half maximum of the 6:1 sample is 1.81 eV. When compared to the polymeric sample, the width is approximately 0.4 eV narrower. This is an indicator of the degree of order in the Si bonding structure. A narrower peak indicates a uniform bonding of the Si. This is a further indicator that the 6:1 sample is SiO₂ and the 0.34:1 sample is a polymer.

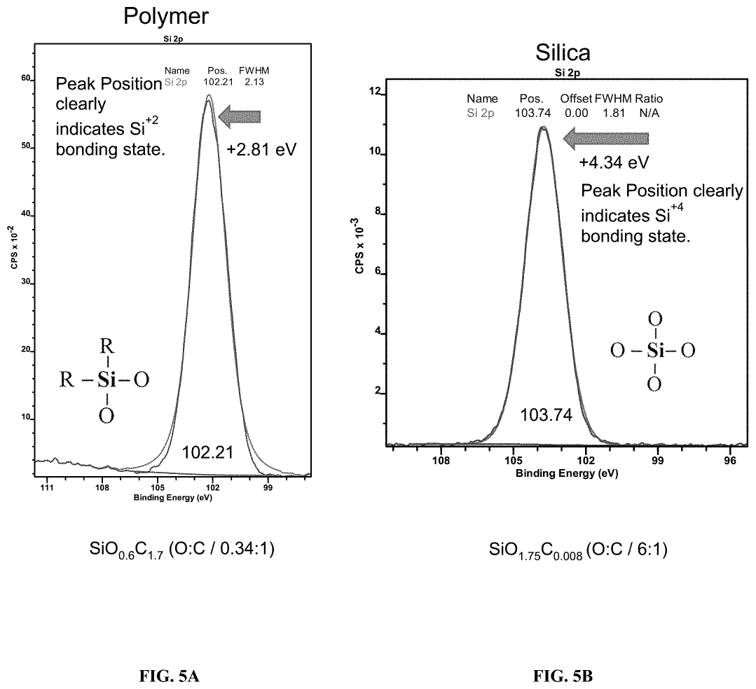

To form a robust water-vapor barrier, alternating layers of polymer (0.34:1) and SiO₂ (6:1) were deposited. FIG. 6 is a cross-sectional scanning electron microscopy (SEM) image for an eleven-layer thin-film stack forming a transparent nano-layered water vapor barrier according to an embodiment. Three-, five-, seven,- and nine-layer samples were also fabricated. The 11-layer sample was selected for further study and discussion as it showed a clear layered structure that could be correlated with the optical and water transmission properties. The substrate used for this sample was a piece of a single crystal Si wafer. The Si wafer substrate was chosen as it permits simple cross-section preparation via cleaving. To avoid thin-film optical interference effects, the target layer thickness should be kept below 65 nm. In the SEM, there are clearly defined layers where the dark layers are the polymeric compound of the first layer 120 film and the brighter layers are the silica-like compound of the second layer 130 film. This 11-layer film was deposited at the same time onto both a polycarbonate substrate and a 20-μm-thick low-density polyethylene (LDPE) film.

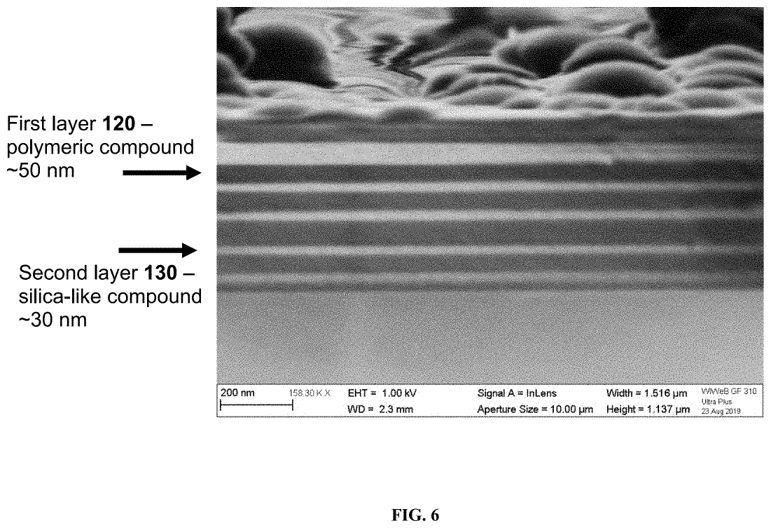

To measure the effect of the 11-layer thin-film stack on the LDPE film, we used a water-vapor transmission rate tester. FIG. 7A is a schematic of the testing setup. A porous polypropylene disc is soaked in a saturated sodium chloride solution. This disc is then placed in a sealed chamber above the sample. The saturated solution has a known vapor pressure and hence provides a fixed relative humidity of 85% for the duration of the experiment. The film is then clamped from both sides with an O-ring to seal the system. On the bottom of the film, a continuous flow of dry nitrogen (N₂) is used to carry away any water vapor that is then continuously analyzed by an electrochemical humidity sensor. Once steady-state is achieved, the water permittivity is recorded and the sample can be removed. In FIG. 7B, the results of the water-transmission measurements are shown for the samples coated with the 11-layer water barrier versus the uncoated LDPE films. There was a 29% decrease seen in the water-transmission rate for the samples with the 11-layer water barrier.

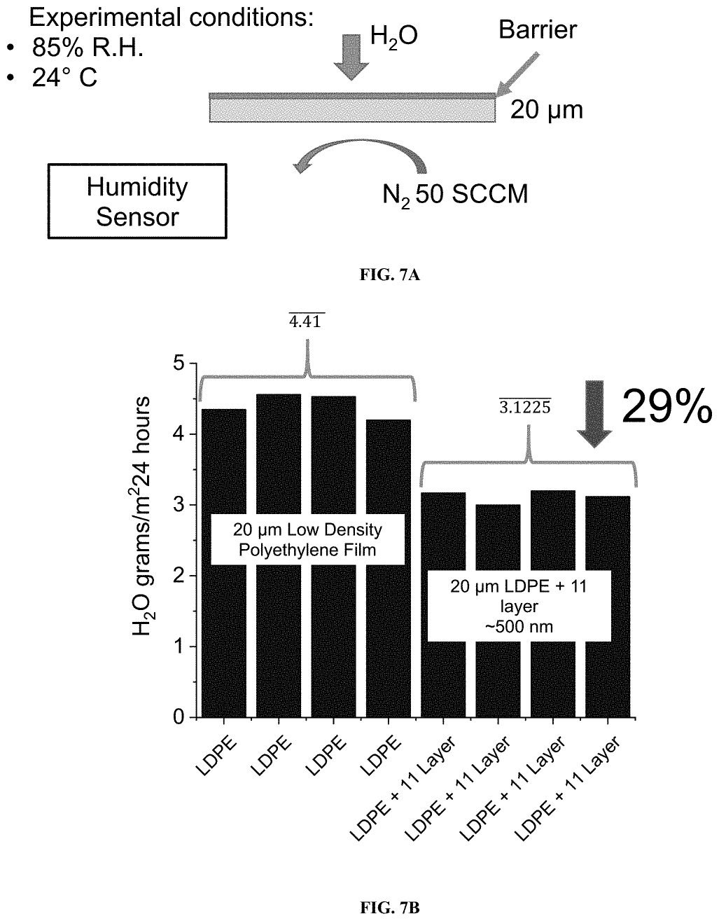

In FIG. 8, the optical transmission data is shown for a series of polycarbonate samples. A PerkinElmer (Waltham, Mass.) double-beam spectrometer was used to acquire the data. In the plot, a break was placed in the y-axis between 20% and 70% transmission, as this was a featureless area of the data. The dotted curve shows the as-received polycarbonate transmission. There is a sinusoidal modulation in the transmission data, which can be attributed to interference fringes from the anti-scratch layer on the polycarbonate. The transmission data show there is a small loss of approximately 2% and approximately 3% in the polymer film (0.35:1) and in the 11-layer film, respectively. These small losses in the specular transmission should not affect the overall visibility.

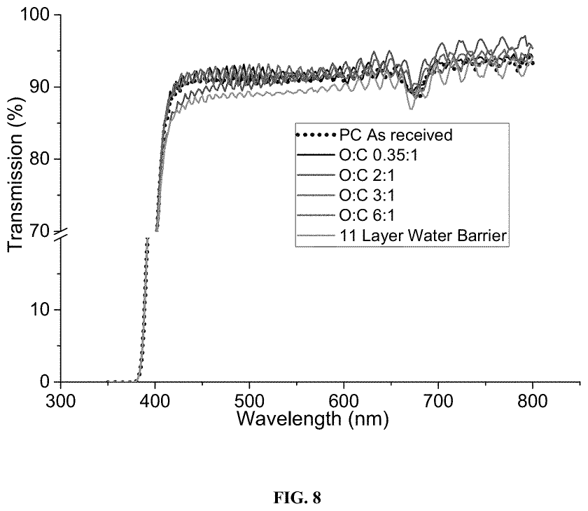

FIG. 9 shows atomic force microscopy (AFM) images of the deposited thin films. A Cypher AFM in noncontact mode was used to acquire the images. The AFM images of the 0.34:1, 2:1, 3:1, and 6:1 ratios all show lateral structures on the tens of nanometer size scale. In images of the 11-layer sample it can be observed that the lateral structures are approximately 100 nm or more.

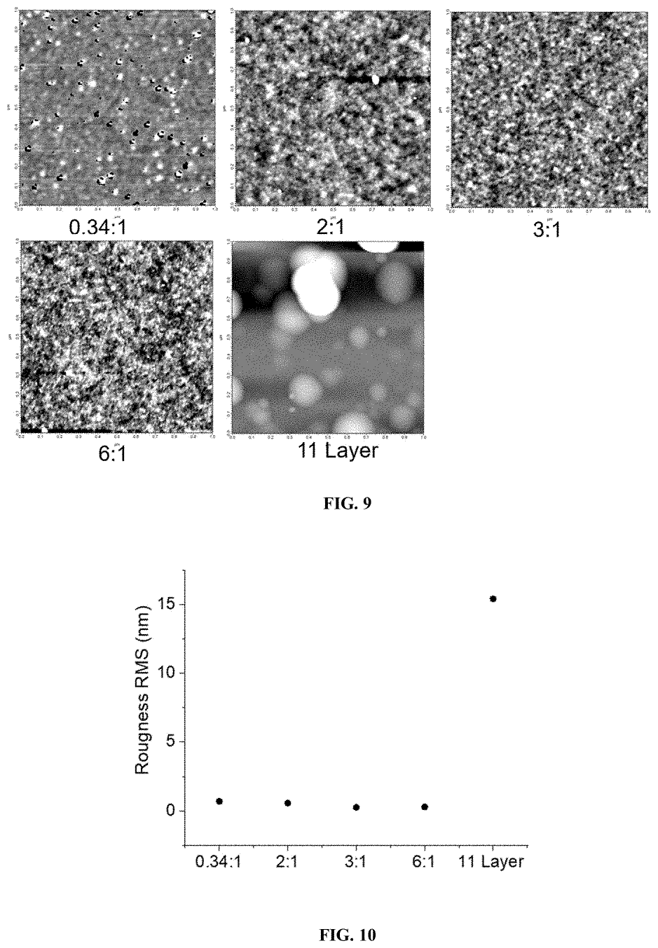

FIG. 10 shows the root mean squared (RMS) roughness of the films. For the single-layer films there is a uniform RMS of less than 1 nm, which is in good agreement with the observed lateral structures in FIG. 9. However, there is a noticeable jump in RMS for the 11-layer sample to 15 nm. This increase makes sense considering the dimension of the lateral structures of the 11-layer film AFM image in the figure. The cross-sectional SEM in FIG. 6 shows that the roughness appears to occur only on the final layer of the film and not through the 11-layer thickness.

The novel technology described herein is designed to reduce the rate of water uptake by polycarbonate and/or other substrate materials, while maintaining optical transparency and can be applied at the end of the manufacturing process. Embodiments of the invention can be applied directly to as received transparent armor or windows. More, embodiments incorporate both the scratch resistance of traditional transparent armor as well as a water vapor barrier. The water vapor barrier will increase the service life by preventing thermo-hydrolytic damage to the chemical structure in the substrate and the resultant embrittlement and delamination.

This also provide benefits for transparent window material used in many architectural applications. Polycarbonate is commonly used when weight must be reduced (vs. conventional glass). Extending the service life of these polycarbonate windows via reduced water intrusion would reduce the cost of ownership of these buildings/structures.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the present disclosure and its practical applications, and to describe the actual partial implementation in the laboratory of the system which was assembled using a combination of existing equipment and equipment that could be readily obtained by the inventors, to thereby enable others skilled in the art to best utilize the invention and various embodiments with various modifications as may be suited to the particular use contemplated.

While the foregoing is directed to embodiments of the present invention, other and further embodiments of the invention may be devised without departing from the basic scope thereof, and the scope thereof is determined by the claims that follow.

We claim:

1. A transparent water vapor barrier comprising:
a substrate; and
one or more transparent bilayers formed on the substrate, each transparent bilayer comprising:
a first layer formed of a polymer film comprising a polymeric compound of Si, O and C; and
a second layer formed of a nearly carbon-free film comprising a silica-like compound of Si and O,
wherein the thickness of the layers is kept below the thin film interference thickness characterized as the wavelength of light (λ) divided by four (4) times the index of refraction (n) of the film materials to ensure that the one or more transparent bilayers are substantially transparent to the light.

2. The barrier according to claim 1, wherein the polymeric compound has a stoichiometry of approximately SiO_{0.6}C_{1.7}.

3. The barrier according to claim 1, wherein the nearly carbon-free film comprises less than about 1 atomic percent carbon.

4. The barrier according to claim 1, wherein the silica-like compound of Si and O comprises SiO_{X}, where 1.25<X<2.

5. The barrier according to claim 1, wherein the silica-like compound has a stoichiometry of approximately SiO_{1.75}C_{0.008}.

6. The barrier according to claim 1, wherein the substrate comprises a transparent armor or window.

7. The barrier according to claim 1, wherein the substrate is formed of polycarbonate, polyvinyl alcohol, acrylonitrile butadiene styrene, or nylon.

8. The barrier of claim 1, wherein A is approximately 380 nm and n is approximately 1.4-1.55.

9. The barrier of claim 8, wherein each film of the one or more transparent bilayers is no more than approximately 60 nm in thickness.

10. A method for forming a transparent water vapor barrier comprising:
placing a substrate in a chamber; and
varying the oxygen:carbon ratio of oxygen and hexamethyldisiloxane (HMDSO) precursor gases supplied to the chamber in a deposition process to form one or more transparent bilayers on the substrate, each transparent bilayer comprising:
a first layer formed of a polymer film comprising a polymeric compound of Si, O and C; and
a second layer formed of a nearly carbon-free film comprising a silica-like compound of Si and O,
wherein the thickness of the layers is kept below the thin film optical interference thickness characterized as the wavelength of light (λ) divided by four (4) times the index of refraction (n) of the deposited film materials so as to ensure that the one or more transparent bilayers are substantially transparent to the light.

11. The method of claim 10, wherein the deposition process comprises plasma assisted chemical vapor deposition.

12. The method of claim 10, where the oxygen:carbon ratio of the precursor gases is approximately 0.34:1 to form the polymer film.

13. The method of claim 10, where the oxygen:carbon ratio of the precursor gases is approximately 6:1 to form the nearly carbon-free film.

14. The method of claim 10, further comprising: cleaning the substrate before placing it into the chamber.

15. The method of claim 10, further comprising: generating a plasma within the chamber to activate the surface of the substrate before forming the one or more transparent bilayers.

16. The method of claim 10, further comprising: supplying a working gas to the chamber to vary the oxygen:carbon ratio of the precursor gases.

17. The method of claim 16, wherein the working gas comprises argon krypton, helium, neon or xenon.

18. The method of claim 10, wherein the chamber is a vacuum chamber.

19. The method of claim 10, further comprising: lowering the pressure in the chamber to about 0.02 mbar or less.

20. A transparent water vapor barrier comprising:
a substrate; and
one or more transparent bilayers formed on the substrate, produced by varying the ratio of oxygen and hexamethyldisiloxane (HMDSO) precursor gases supplied to a chamber in a deposition process, each transparent bilayer comprising:
a first layer formed of a polymer film comprising a polymeric compound of Si, O and C; and
a second layer formed of a nearly carbon-free film comprising a silica-like compound of Si and O,
wherein the thickness of the layers is kept below the thin film interference thickness to ensure the one or more transparent bilayers are substantially transparent to the light.
